(19) United States
(12) Patent Application Publication
(10) Pub. No.: US 2017/0025480 A1
(43) Pub. Date: Jan. 26, 2017

(54) IN-CELL TOUCH PANEL

(71) Applicant: Raydium Semiconductor Corporation, Hsinchu (TW)

(72) Inventors: Chang-Ching CHIANG, Taichung City (TW); Yi-Ying LIN, Hualien City (TW); Kun-Pei LEE, Zhunan Township (TW)

(21) Appl. No.: 15/170,640

(22) Filed: Jun. 1, 2016

Related U.S. Application Data
(60) Provisional application No. 62/194,704, filed on Jul. 20, 2015.

(51) Int. Cl. H01L 27/32; G06F 3/044; H01L 51/52; G06F 3/041

(52) U.S. Cl. CPC H01L 27/323; G06F 3/0412; G06F 3/044; H01L 51/5253; H01L 51/5284; H01L 51/5281; H01L 51/5275; H01L 27/3272

(57) ABSTRACT

An in-cell touch panel is disclosed. The in-cell touch panel includes a plurality of pixels. A laminated structure of each pixel includes a substrate, an OLED layer, an encapsulation layer, a light-blocking layer, a first conductive layer and a second conductive layer. The OLED layer is disposed above the substrate. The encapsulation layer is disposed above the OLED layer opposite to the substrate. The first conductive layer is disposed under the light-blocking layer. The second conductive layer is disposed under the encapsulation layer.

### BACKGROUND OF THE INVENTION

Field of the Invention

This invention relates to a touch panel, especially to an in-cell touch panel.

Description of the Related Art

In general, capacitive touch panels using active matrix organic light emitting diode (AMOLED) display technology can be divided into different types based on their different laminated structures, such as in-cell AMOLED capacitive touch panels and on-cell AMOLED capacitive touch panels.

Please refer to FIG. 1 and FIG. 2. FIG. 1 and FIG. 2 illuminate schematic diagrams of the laminated structures of the on-cell AMOLED capacitive touch panel and the in-cell AMOLED capacitive touch panel respectively. As shown in FIG. 1, the laminated structure 1 of the on-cell AMOLED capacitive touch panel includes a substrate 10, an AMOLED layer 11, an encapsulation layer 12, a touch sensing layer 13, a polarizer 14, an adhesive 15 and a top cover lens 16 from the bottom up. As shown in FIG. 2, the laminated structure 2 of the in-cell AMOLED capacitive touch panel includes a substrate 20, an AMOLED layer 21, a touch sensing layer 22, an encapsulation layer 23, a polarizer 24, an adhesive 25 and a top cover lens 26 from the bottom up.

After comparing FIG. 1 with FIG. 2, it can be found that the touch sensing layer 22 of the in-cell AMOLED capacitive touch panel is disposed under the encapsulation layer 23, namely the touch sensing layer 22 is disposed in the AMOLED display module; the touch sensing layer 13 of the on-cell AMOLED capacitive touch panel is disposed above the encapsulation layer 12, namely the touch sensing layer 13 is disposed out of the AMOLED display module. Compared to the conventional one glass solution (OGS) AMOLED capacitive touch panel and the on-cell AMOLED capacitive touch panel, the in-cell AMOLED capacitive touch panel can achieve the thinnest AMOLED touch panel design and it can be widely used in portable electronic products such as cell phones, tablet PCs and notebook PCs.

Therefore, the invention provides an in-cell touch panel having novel layout to simplify the design of circuit traces and reduce the effects of resistance and parasitic capacitance to enhance the entire performance of the in-cell touch panel and solve the above-mentioned problems.

### SUMMARY OF THE INVENTION

An embodiment of the invention is an in-cell touch panel. In this embodiment, the in-cell touch panel includes a plurality of pixels. A laminated structure of each pixel includes a substrate, an OLED layer, an encapsulation layer, a light-blocking layer, a first conductive layer and a second conductive layer. The OLED layer is disposed above the substrate. The encapsulation layer is disposed above the OLED layer opposite to the substrate. The first conductive layer is disposed under the light-blocking layer. The second conductive layer is disposed under the encapsulation layer.

In an embodiment, the in-cell touch panel is an in-cell self-capacitive touch panel or an in-cell mutual-capacitive touch panel.

In an embodiment, the second conductive layer is formed after the first conductive layer.

In an embodiment, the second conductive layer is formed before the first conductive layer.

In an embodiment, an insulating layer is formed between the first conductive layer and the second conductive layer.

In an embodiment, the first conductive layer and the second conductive layer are electrically connected through a via formed in the insulating layer.

In an embodiment, the first conductive layer and the second conductive layer are electrically connected by direct contact without any insulating layer formed between the first conductive layer and the second conductive layer.

In an embodiment, the first conductive layer and the second conductive layer are not electrically connected.

In an embodiment, the light-blocking layer is formed by opaque material and the light-blocking layer is disposed above a non-luminous area of the OLED layer.

In an embodiment, the second conductive layer is formed by transparent conductive material and the second conductive layer is used to form touch sensing electrodes of the in-cell touch panel.

In an embodiment, the first conductive layer is electrically connected with the second conductive layer and used as traces of the touch sensing electrodes of the in-cell touch panel.

In an embodiment, the traces of different touch sensing electrodes of the in-cell touch panel are disconnected.

In an embodiment, the second conductive layer forming different parts of different touch sensing electrodes of the in-cell touch panel are disconnected.

In an embodiment, one of the touch sensing electrodes of the in-cell touch panel is electrically connected to a plurality of traces respectively to reduce a resistance of the touch sensing electrode.

In an embodiment, one touch sensing electrode of the in-cell touch panel and a trace of another touch sensing electrode of the in-cell touch panel are not overlapped.

Compared with the prior arts, the invention has the following advantages and effects:
(1) The designs of touch electrodes and their traces are simple.
(2) The optical effects on the AMOLED touch panel can be effectively reduced by the novel layout method.
(3) The RC loading of the touch electrodes can be effectively reduced.
(4) The module thickness of the AMOLED touch panel can be effectively reduced.

The advantage and spirit of the invention may be understood by the following detailed descriptions together with the appended drawings.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 and FIG. 2 illuminate schematic diagrams of the laminated structures of the on-cell AMOLED capacitive touch panel and the in-cell AMOLED capacitive touch panel respectively.

FIG. 3 illuminates the laminated structure of the pixel of the in-cell touch panel in the first embodiment of the invention.

FIG. 4 illuminates the laminated structure of the pixel of the in-cell touch panel in the second embodiment of the invention.

FIG. 5 illuminates the laminated structure of the pixel of the in-cell touch panel in the third embodiment of the invention.

FIG. 6 illuminates the laminated structure of the pixel of the in-cell touch panel in the fourth embodiment of the invention.

FIG. 7 and FIG. 8 illuminate different embodiments of the light-blocking layer disposed above the encapsulation layer respectively.

FIG. 9 and FIG. 10 illuminate different layout methods of the sensing electrodes and their traces of the in-cell touch panel of the invention respectively.

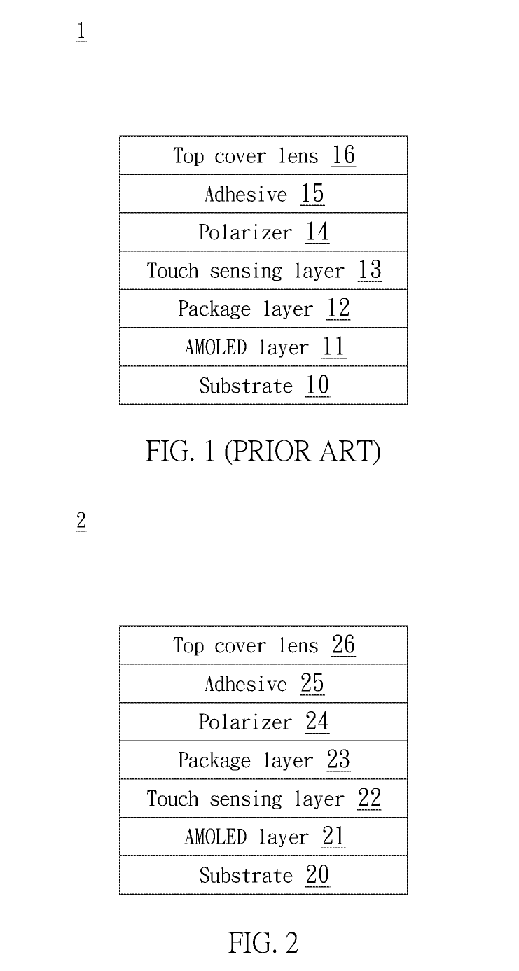

### DETAILED DESCRIPTION

The invention discloses an in-cell touch panel. In practical applications, the in-cell touch panel of the invention can be an in-cell self-capacitive touch panel or an on-cell self-capacitive touch panel without any specific limitations. The in-cell touch panel includes a plurality of pixels. The actual design of the in-cell touch panel can be designed in different ways based on different panels and characteristics.

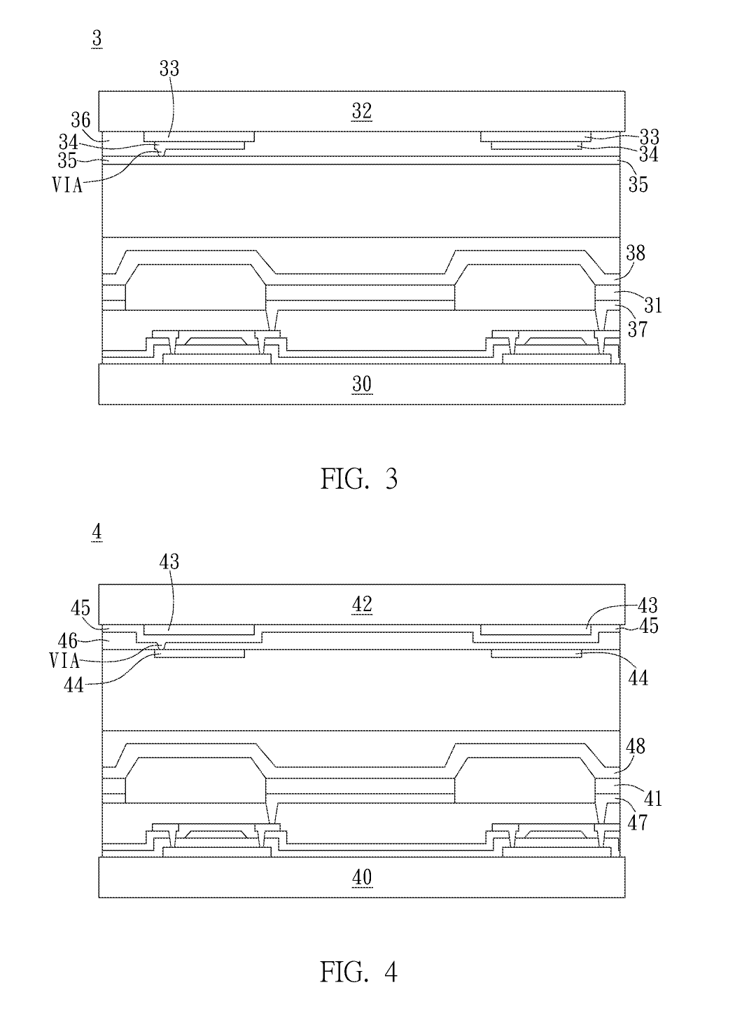

At first, please refer to FIG. 3. FIG. 3 illuminates the laminated structure of the pixel of the in-cell touch panel in the first embodiment of the invention.

As shown in FIG. 3, the laminated structure 3 includes a substrate 30, an OLED layer 31, an encapsulation layer 32, a light-blocking layer 33, a first conductive layer 34, a second conductive layer 35, an insulating layer 36, an anode layer 37 and a cathode layer 38. The OLED layer 31 is disposed above the substrate 30. The encapsulation layer 32 is disposed above the OLED layer 31 opposite to the substrate 30. The first conductive layer 34 is disposed under the light-blocking layer 33. The second conductive layer 35 is disposed under the encapsulation layer 32. The anode layer 37 is disposed under the OLED layer 31 and the cathode layer 38 is disposed above the OLED layer 31 respectively.

It should be noticed that the second conductive layer 35 in this embodiment is formed before the first conductive layer 34, and there is an insulating layer 36 formed between the first conductive layer 34 and the second conductive layer 35. The light-blocking layer 33 is formed by opaque material and the light-blocking layer 33 is disposed above a non-luminous area (e.g., gate lines or signal lines) of the OLED layer 31. The second conductive layer 35 is formed by transparent conductive material and the second conductive layer 35 is used to form touch sensing electrodes of the in-cell touch panel.

From FIG. 3, it can be found that the first conductive layer 34 and the second conductive layer 35 can be electrically connected through a via VIA formed in the insulating layer 36, or the first conductive layer 34 and the second conductive layer 35 are not electrically connected without specific limitations. The first conductive layer 34 can be formed by transparent or opaque conductive material. When the first conductive layer 34 disposed under the light-blocking layer 33 is electrically connected with the second conductive layer 35, the first conductive layer 34 can be used as traces of the touch sensing electrodes of the in-cell touch panel, but not limited to this.

Then, please refer to FIG. 4. FIG. 4 illuminates the laminated structure of the pixel of the in-cell touch panel in the second embodiment of the invention.

As shown in FIG. 4, the laminated structure 4 includes a substrate 40, an OLED layer 41, an encapsulation layer 42, a light-blocking layer 43, a first conductive layer 44, a second conductive layer 45, an insulating layer 46, an anode layer 47 and a cathode layer 48. The OLED layer 41 is disposed above the substrate 40. The encapsulation layer 42 is disposed above the OLED layer 41 opposite to the substrate 40. The first conductive layer 44 is disposed under the light-blocking layer 43. The second conductive layer 45 is disposed under the encapsulation layer 42. The anode layer 47 is disposed under the OLED layer 41 and the cathode layer 48 is disposed above the OLED layer 41 respectively.

It should be noticed that the second conductive layer 45 in this embodiment is formed after the first conductive layer 44, and there is an insulating layer 46 formed between the first conductive layer 44 and the second conductive layer 45. The light-blocking layer 43 is formed by opaque material and the light-blocking layer 43 is disposed above a non-luminous area of the OLED layer 41. The second conductive layer 45 is formed by transparent conductive material and the second conductive layer 45 is used to form touch sensing electrodes of the in-cell touch panel.

From FIG. 4, it can be found that the first conductive layer 44 and the second conductive layer 45 can be electrically connected through a via VIA formed in the insulating layer 46, or the first conductive layer 44 and the second conductive layer 45 are not electrically connected without specific limitations. The first conductive layer 44 can be formed by transparent or opaque conductive material. When the first conductive layer 44 disposed under the light-blocking layer 43 is electrically connected with the second conductive layer 45, the first conductive layer 44 can be used as traces of the touch sensing electrodes of the in-cell touch panel, but not limited to this.

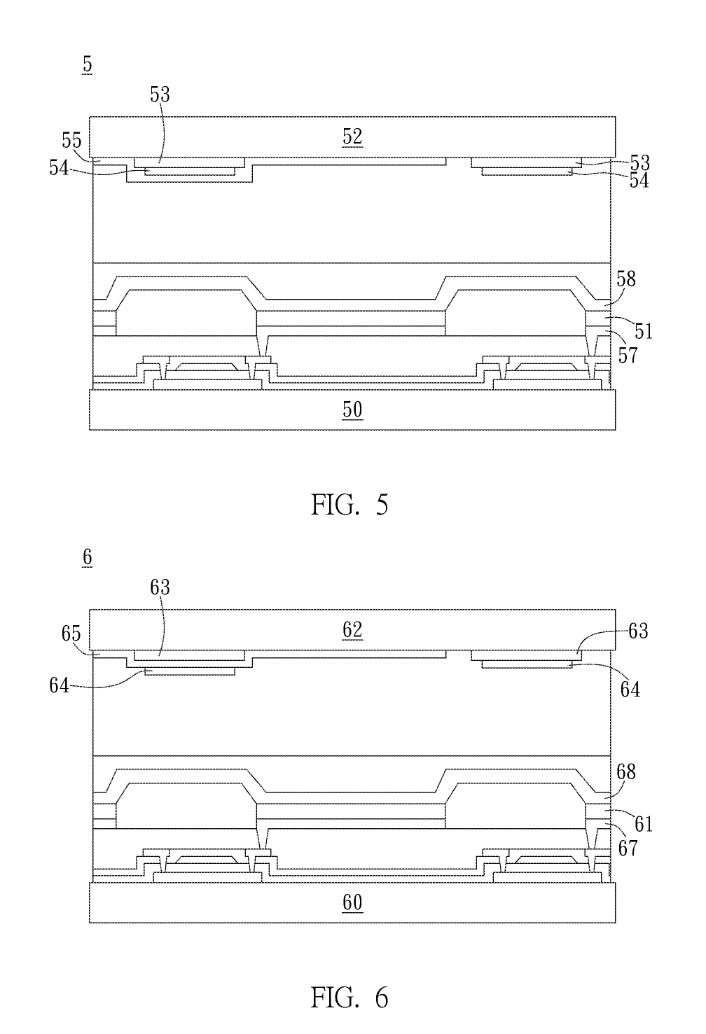

Then, please refer to FIG. 5. FIG. 5 illuminates the laminated structure of the pixel of the in-cell touch panel in the third embodiment of the invention.

As shown in FIG. 5, the laminated structure 5 includes a substrate 50, an OLED layer 51, an encapsulation layer 52, a light-blocking layer 53, a first conductive layer 54, a second conductive layer 55, an anode layer 57 and a cathode layer 58. The OLED layer 51 is disposed above the substrate 50. The encapsulation layer 52 is disposed above the OLED layer 51 opposite to the substrate 50. The first conductive layer 54 is disposed under the light-blocking layer 53. The second conductive layer 55 is disposed under the encapsulation layer 52. The anode layer 57 is disposed under the OLED layer 51 and the cathode layer 58 is disposed above the OLED layer 51 respectively.

It should be noticed that the second conductive layer 55 in this embodiment is formed before the first conductive layer 54, and there is no insulating layer formed between the first conductive layer 54 and the second conductive layer 55. From FIG. 5, it can be found that the first conductive layer 54 and the second conductive layer 55 can be electrically connected in a direct contact way or the first conductive layer 54 and the second conductive layer 55 are not electrically connected without any specific limitations. The light-blocking layer 53 is formed by opaque material and the light-blocking layer 53 is disposed above a non-luminous area of the OLED layer 51. The second conductive layer 55 is formed by transparent conductive material and the second conductive layer 55 is used to form touch sensing electrodes of the in-cell touch panel. The first conductive layer 54 can be formed by transparent or opaque conductive material. When the first conductive layer 54 disposed under the light-blocking layer 53 is electrically connected with the second conductive layer 55, the first conductive layer 54 can be used as traces of the touch sensing electrodes of the in-cell touch panel, but not limited to this.

Afterwards, please refer to FIG. 6. FIG. 6 illuminates the laminated structure of the pixel of the in-cell touch panel in the fourth embodiment of the invention.

As shown in FIG. 6, the laminated structure 6 includes a substrate 60, an OLED layer 61, an encapsulation layer 62, a light-blocking layer 63, a first conductive layer 64, a second conductive layer 65, an anode layer 67 and a cathode layer 68. The OLED layer 61 is disposed above the substrate 60. The encapsulation layer 62 is disposed above the OLED layer 61 opposite to the substrate 60. The first conductive layer 64 is disposed under the light-blocking layer 63. The second conductive layer 65 is disposed under the encapsulation layer 62. The anode layer 67 is disposed under the OLED layer 61 and the cathode layer 68 is disposed above the OLED layer 61 respectively.

It should be noticed that the second conductive layer 65 in this embodiment is formed after the first conductive layer 64, and there is no insulating layer formed between the first conductive layer 64 and the second conductive layer 65. From FIG. 6, it can be found that the first conductive layer 64 and the second conductive layer 65 can be electrically connected in a direct contact way or the first conductive layer 64 and the second conductive layer 65 are not electrically connected without any specific limitations. The light-blocking layer 63 is formed by opaque material and the light-blocking layer 63 is disposed above a non-luminous area of the OLED layer 61. The second conductive layer 65 is formed by transparent conductive material and the second conductive layer 65 is used to form touch sensing electrodes of the in-cell touch panel. The first conductive layer 64 can be formed by transparent or opaque conductive material. When the first conductive layer 64 disposed under the light-blocking layer 63 is electrically connected with the second conductive layer 65, the first conductive layer 64 can be used as traces of the touch sensing electrodes of the in-cell touch panel, but not limited to this.

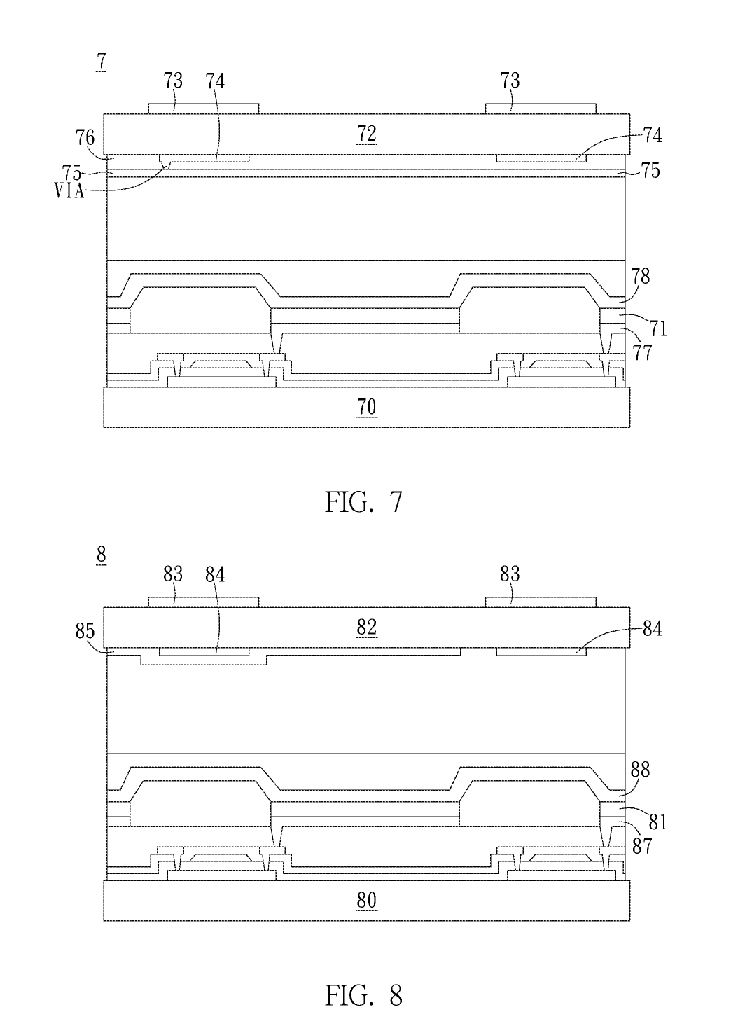

In addition, it should be noted that the light-blocking layers 33, 43, 53 and 63 are all disposed under the encapsulation layers 32, 42, 52 and 62 in the first embodiment through the fourth embodiment shown in FIG. 3 through FIG. 6. However, in practical applications, as shown in FIG. 7 and FIG. 8, the light-blocking layers 73 and 83 can be disposed above the encapsulation layers 72 and 82 respectively to effectively shelter the first conductive layers 74 and 84 disposed under the encapsulation layers 72 and 82.

Except the above-mentioned embodiments, the invention can be practiced in the in-cell touch panels having the laminated structure including white-light OLED and color filtering layer or other laminated structures without any specific limitations.

Then, the following two embodiments will be used to explain different sensing electrode and trace layouts of the in-cell touch panel.

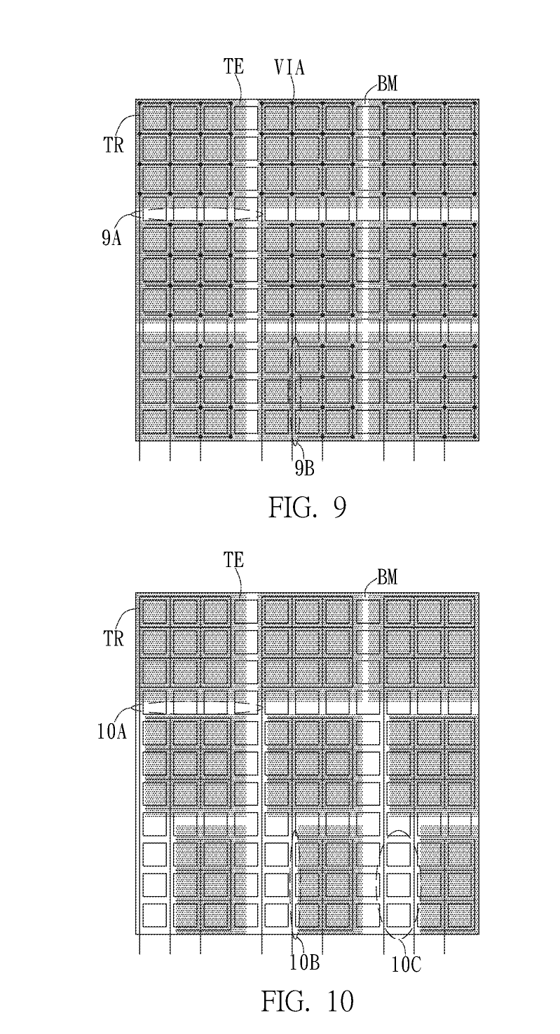

In an embodiment, as shown in FIG. 9, the light-blocking layer BM formed by opaque material is disposed on the encapsulation layer and overlapped above the non-luminous area (e.g., gate lines or signal lines) of the OLED layer. The first conductive layer sheltered by the light-blocking layer BM forms the traces TR of the touch sensing electrodes and the traces TR of different touch sensing electrodes of the in-cell touch panel are disconnected (as shown in the region 9B in FIG. 9). The touch sensing electrode TE formed by the transparent second conductive layer (e.g., ITO) can be electrically connected with the touch sensing electrode traces TR through via VIA. And, the resistance can be reduced by electrically connecting with a plurality of touch sensing electrode traces TR through via VIA respectively within the touch sensing electrodes TE.

As shown in the region 9A in FIG. 9, the second conductive layer forming different parts of different touch sensing electrodes of the in-cell touch panel can be disconnected and the traces TR of different touch sensing electrodes of the in-cell touch panel can be also disconnected.

It should be noticed that the panel layout shown in FIG. 9 can correspond to the laminated structures 3 and 4 of FIG. 3 and FIG. 4, but not limited to this.

In another embodiment, as shown in FIG. 10, the light-blocking layer BM formed by opaque material is disposed on the encapsulation layer and overlapped above the non-luminous area (e.g., gate lines or signal lines) of the OLED layer. The first conductive layer sheltered by the light-blocking layer BM forms the traces TR of the touch sensing electrodes and the traces TR of different touch sensing electrodes of the in-cell touch panel are disconnected (as shown in the region 10B in FIG. 10). The touch sensing electrode TE formed by the transparent second conductive layer (e.g., ITO) can be electrically connected with the touch sensing electrode traces TR in a direct contact way. And, the resistance can be reduced by disposing a plurality of touch sensing electrode traces TR within the touch sensing electrodes TE.

As shown in the region 10A in FIG. 10, the second conductive layer forming different parts of different touch sensing electrodes TE of the in-cell touch panel can be disconnected and the traces TR of different touch sensing electrodes of the in-cell touch panel can be also disconnected. The traces TR of different touch sensing electrodes of the in-cell touch panel will not be overlapped.

As shown in the region 10C in FIG. 10, the second conductive layer (e.g., ITO) forming a touch sensing electrode TE and the trace TR of another touch sensing electrode TE will not be overlapped. It should be noticed that the panel layout shown in FIG. 10 can correspond to the laminated structures 5 and 6 of FIG. 5 and FIG. 6, but not limited to this.

Compared with the prior arts, the invention has the following advantages and effects:
(1) The designs of touch electrodes and their traces are simple.
(2) The optical effects on the AMOLED touch panel can be effectively reduced by the novel layout method.
(3) The RC loading of the touch electrodes can be effectively reduced.
(4) The module thickness of the AMOLED touch panel can be effectively reduced.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

1. An in-cell touch panel, comprising:
a plurality of pixels, a laminated structure of each pixel comprising:
a substrate;
an OLED layer disposed above the substrate;
an encapsulation layer disposed above the OLED layer opposite to the substrate;
a light-blocking layer;
a first conductive layer disposed under the light-blocking layer; and
a second conductive layer disposed under the encapsulation layer.

2. The in-cell touch panel of claim 1, wherein the in-cell touch panel is an in-cell self-capacitive touch panel or an in-cell mutual-capacitive touch panel.

3. The in-cell touch panel of claim 1, wherein the second conductive layer is formed after the first conductive layer.

4. The in-cell touch panel of claim 1, wherein the second conductive layer is formed before the first conductive layer.

5. The in-cell touch panel of claim 1, wherein an insulating layer is formed between the first conductive layer and the second conductive layer.

6. The in-cell touch panel of claim 5, wherein the first conductive layer and the second conductive layer are electrically connected through a via formed in the insulating layer.

7. The in-cell touch panel of claim 1, wherein the first conductive layer and the second conductive layer are electrically connected by direct contact without any insulating layer formed between the first conductive layer and the second conductive layer.

8. The in-cell touch panel of claim 1, wherein the first conductive layer and the second conductive layer are not electrically connected.

9. The in-cell touch panel of claim 1, wherein the light-blocking layer is formed by opaque material and the light-blocking layer is disposed above a non-luminous area of the OLED layer.

10. The in-cell touch panel of claim 1, wherein the second conductive layer is formed by transparent conductive material and the second conductive layer is used to form touch sensing electrodes of the in-cell touch panel.

11. The in-cell touch panel of claim 10, wherein the first conductive layer is electrically connected with the second conductive layer and used as traces of the touch sensing electrodes of the in-cell touch panel.

12. The in-cell touch panel of claim 11, wherein the traces of different touch sensing electrodes of the in-cell touch panel are disconnected.

13. The in-cell touch panel of claim 10, wherein the second conductive layer forming different parts of different touch sensing electrodes of the in-cell touch panel are disconnected.

14. The in-cell touch panel of claim 10, wherein one of the touch sensing electrodes of the in-cell touch panel is electrically connected to a plurality of traces respectively to reduce a resistance of the touch sensing electrode.

15. The in-cell touch panel of claim 10, wherein one touch sensing electrode of the in-cell touch panel and a trace of another touch sensing electrode of the in-cell touch panel are not overlapped.
